(19) United States
(12) Patent Application Publication
(10) Pub. No.: US 2006/0198306 A1
(43) Pub. Date: Sep. 7, 2006

(54) SYSTEM AND METHOD FOR CONTROLLING A SERVICE TO USE A RESOURCE

(76) Inventor: Cheng-Yin Shen, Shenzhen (CN)

Correspondence Address: NORTH AMERICA INTELLECTUAL PROPERTY CORPORATION, P.O. BOX 506, MERRIFIELD, VA, 22116, US

(21) Appl. No.: 11/164,885

(22) Filed: Dec. 8, 2005

(30) Foreign Application Priority Data
Dec. 17, 2004 (TW) 093139412

(51) Int. Cl. H04L 12/26; G01R 31/08; G06F 11/00; G08C 15/00

(52) U.S. Cl. 370/236.1

(57) ABSTRACT

A system for controlling a service to use a resource is disclosed. The system includes: an active bitmap obtaining module (21) for obtaining an active bitmap of the resource; an blacklist bitmap obtaining module (22) for obtaining a blacklist bitmap of the service; a checking module (23) for determining whether there is any service in the blacklist bitmap of the service which is also in the active bitmap of the resource; and a message returning module (24) for returning a message according to different results of the service using the resource. A related method is also disclosed.

### FIELD OF THE INVENTION

The present invention relates to a system and method for controlling a service to use a resource.

### DESCRIPTION OF RELATED ART

In computer systems, there are many resources, such as CPUs, memories, hard disks, CD/DVD ROMs, tape devices and so on. Each computer system provides large numbers of services for users. During the period of running the services, corresponding resources need to be used. Before a service begins to use a resource, the computer system always needs to generate a request of using the resource by the service, and then, the corresponding resource releases a license to the service. After the service obtains the license, the service can use the resource.

However, something unpredictable may occur after the service gets the license. For example, when an error occurs, the license of using the resource by the service cannot be withdrew by using conventional technologies, and the resource would be occupied by the service enduringly when the computer system is working.

Therefore, what is needed is a method for controlling a service to use a resource, in which the service can use the resource safely and efficiently.

### SUMMARY OF INVENTION

A system for controlling a service to use a resource is provided. The system includes: an active bitmap obtaining module for obtaining an active bitmap of the resource, and releasing the active bitmap of the resource when the service finishes using the resource; an blacklist bitmap obtaining module for obtaining a blacklist bitmap of the service, and releasing the blacklist bitmap of the service when the service finishes using the resource; a checking module for determining whether there is any service in the blacklist bitmap of the service which is also in the active bitmap of the resource, and adding the service to the active bitmap of the resource if no such service exists; and a message returning module for returning a message according to different results of the service using the resource.

A method for controlling a service to use a resource is provided. The method includes the steps of: starting the service; obtaining an active bitmap of the resource; obtaining a blacklist bitmap of the service; determining whether there is any service in the blacklist bitmap which is also in the active bitmap; adding the service to the active bitmap if no such service exists; releasing the active bitmap and the blacklist bitmap; and returning a truth message.

Other advantages and novel features of the embodiments will be drawn from the following detailed description with reference to the attached drawings, in which:

### BRIEF DESCRIPTION OF DRAWINGS

FIG. 1 is a schematic diagram of an application environment of a system for controlling a service to use a resource in accordance with a preferred embodiment;

FIG. 2 is a schematic diagram of main function modules of an application server of FIG. 1; and

FIG. 3 is a flowchart of a preferred method for controlling a service to use a resource.

### DETAILED DESCRIPTION

In order to describe the preferred embodiment conveniently, the following are definitions of important technical terms used in the preferred embodiment: (1) Active bitmap: a bitmap which belongs to a resource and records at least one service using the resource currently. For example, a file is viewed as a resource in a computer system, which can be used by various services, such as A, B, C and D. Supposing that the file are being used by the services A, B and C, the active bitmap of the file records the services A, B and C; (2) Blacklist bitmap: a bitmap which belongs to a service and records at least one service which cannot share a resource with the service at the same time. For example, a service E denotes reading data from a hard disk, and a service F denotes formatting the hard disk. Obviously, the service E and the service F cannot work at the same time on the hard disk. Therefore, the blacklist bitmap of the service E records the service F.

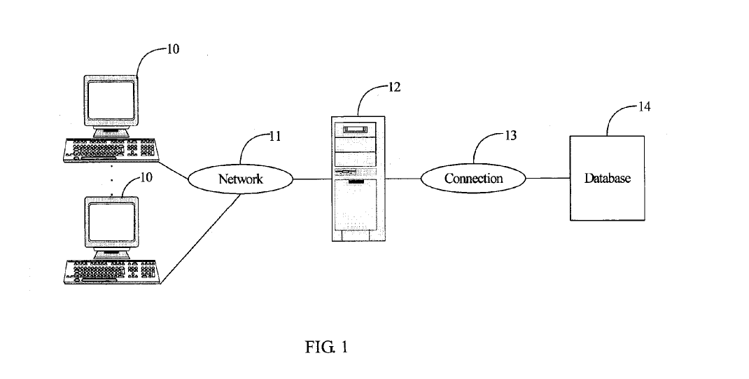

FIG. 1 is a schematic diagram of an application environment of a system for controlling a service to use a resource. The application environment may include a plurality of client computers 10, a network 11, an application sever 12, a connection 13 and a database 14. The client computers 10 are connected to the application sever 12 via the network 11. The application sever 12 is connected to the database 14 via the connection 13.

Each client computer 10 may be a Personal Computer (PC) or a Personal Digital Assistant (PDA), by which a user can send an instruction of controlling a service to use a resource to the application server. The network 11 may be a Local Area Network (LAN), an Intranet or the Internet. The database 14 is used for storing various resources, active bitmaps of the resources, and blacklist bitmaps of various services. The resources may be software resources or hardware resources.

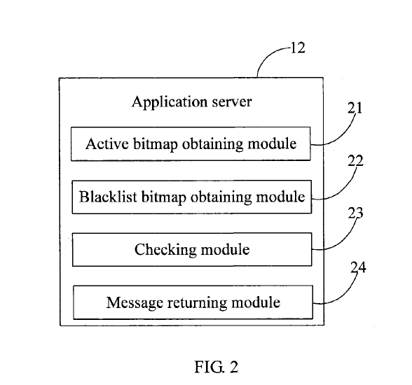

FIG. 2 is a schematic diagram of main function modules of the application server 12. The application sever 12 includes an active bitmap obtaining module 21, a blacklist bitmap obtaining module 22, a checking module 23, and a message returning module 24. The active bitmap obtaining module 21 is used for obtaining an active bitmap of a resource from the database 14 when a service needs to use the resource according to an instruction from any client computer 10, and releasing the active bitmap of the resource when the service finishes using the resource. The blacklist bitmap obtaining module 22 is used for obtaining a blacklist bitmap of the service from the database 14, and releasing the blacklist bitmap of the service when the service finishes using the resource. The checking module 23 is used for determining whether there is any service in the blacklist bitmap of the service which is also in the active bitmap of the resource, and adding the service to the active bitmap of the resource if no such service exists. The message returning module 24 is used for returning a message to the client computer 10 according to different results of the service using the resource. For example, the message returning module 24 returns a truth message when the service uses the resource successfully, or returns a false message when the service cannot use the resource.

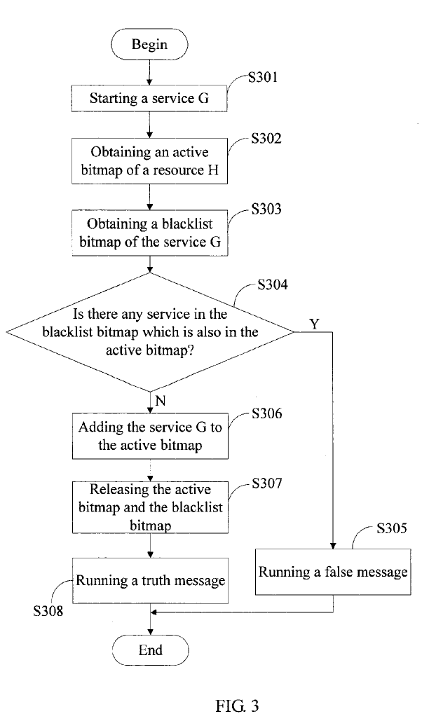

FIG. 3 is a flowchart of a preferred method for controlling a service to use a resource. In step S301, when a user sends an instruction of controlling a service G to use a resource H through a client computer 10, the application server 12 generates a request of using the resource H. Then, the service G is started. In step S302, the active bitmap obtaining module 21 obtains an active bitmap of the resource H. The active bitmap records at least one service which is using the resource H. In step S303, the blacklist bitmap obtaining module 22 obtains a blacklist bitmap of the service G. The blacklist bitmap records at least one service which cannot share the resource H with the service G when the service G is using the resource H. In step S304, the checking module 23 determines whether there is any service in the blacklist bitmap of the service G which is also in the active bitmap of the resource H. If such a service exists, in step S305, the message returning module 24 returns a false message which means that the service G cannot use the resource H, whereupon the procedure ends. Otherwise, if no such service exists, in step S306, the checking module 23 adds the service G to the active bitmap of the resource H. In step S307, the active bitmap obtaining module 21 releases the active bitmap of the resource H, and the blacklist bitmap obtaining module 22 releases the blacklist bitmap of the service G, when the service G finishes using the resource H. In step S308, the message returning module 24 returns a truth message which means that the service G uses the resource H successfully.

Although the present invention has been specifically described on the basis of a preferred embodiment and preferred method, the invention is not to be construed as being limited thereto. Various changes or modifications may be made to the embodiment and method without departing from the scope and spirit of the invention.

What is claimed is:

1. A system for controlling a service to use a resource, the system comprising:
an active bitmap obtaining module for obtaining an active bitmap of the resource, and releasing the active bitmap of the resource when the service finishes using the resource;
an blacklist bitmap obtaining module for obtaining a blacklist bitmap of the service, and releasing the blacklist bitmap of the service when the service finishes using the resource;
a checking module for determining whether there is any service in the blacklist bitmap of the service which is also in the active bitmap of the resource, and adding the service to the active bitmap of the resource if no such service exists; and
a message returning module for returning a message according to different results of the service using the resource.

2. The system according to claim 1, wherein the active bitmap records at least one service which is using the resource currently.

3. The system according to claim 1, wherein the blacklist bitmap records at least one service which cannot share the resource with the service when the service is using the resource.

4. The system according to claim 1, wherein the message returning module returns a truth message when the service uses the resource successfully, or returns a false message when the service cannot use the resource.

5. A method for controlling a service to use a resource, the method comprising the steps of:
starting the service;
obtaining an active bitmap of the resource;
obtaining a blacklist bitmap of the service;
determining whether there is any service in the blacklist bitmap which is also in the active bitmap;
adding the service to the active bitmap if no such service exists;
releasing the active bitmap and the blacklist bitmap; and
returning a truth message.

6. The method according to claim 5, further comprises the step of:
returning a false message there is any service in the blacklist bitmap which is also in the active bitmap.

7. The method according to claim 5, wherein the active bitmap records at least one service which is using the resource currently.

8. The method according to claim 5, wherein the blacklist bitmap records at least one service which cannot share the resource with the service when the service is using the resource.
